(19) United States
(12) Patent Application Publication
(10) Pub. No.: US 2023/0288810 A1
(43) Pub. Date: Sep. 14, 2023

(54) METHOD OF FORMING A STRUCTURE COMPRISING A PHOTORESIST UNDERLAYER

(71) Applicant: ASM IP Holding B.V., Almere (NL)

(72) Inventors: Fanyong Ran, Tokyo (JP); Jérôme Samuel Nicolas, Tokyo (JP)

(21) Appl. No.: 18/116,973

(22) Filed: Mar. 3, 2023

Related U.S. Application Data
(60) Provisional application No. 63/317,678, filed on Mar. 8, 2022.

(51) Int. Cl. G03F 7/16; G03F 7/11

(52) U.S. Cl. CPC G03F 7/167; G03F 7/11

(57) ABSTRACT

Methods of forming structures including photoresist underlayers including a bulk layer and an adhesion layer are disclosed. Exemplary methods include forming the bulk layer and forming an adhesion layer using plasma-enhanced cyclical deposition processes. The adhesion layer can be formed within the same reaction chamber used to form the bulk layer.

### CROSS-REFERENCE TO RELATED APPLICATIONS

This application claims priority to U.S. Provisional Patent Application Ser. No. 63/317,678 filed Mar. 8, 2022 titled METHOD OF FORMING A STRUCTURE COMPRISING A PHOTORESIST UNDERLAYER, the disclosure of which is hereby incorporated by reference in its entirety.

### FIELD OF INVENTION

The present disclosure generally relates to methods and structures suitable for use with photoresist patterning techniques. More particularly, the disclosure relates to structures including or formed using a photoresist underlayer and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features (e.g., 10 nm or less). EUV dose is typically much higher than radiation doses for other types of photoresist (e.g., 193 nm argon fluoride laser (193i ArF) photoresist), because a number of EUV photons is only about 1/14 of photons produced using ArF at the same dose, and the photon absorption of EUV photoresist is generally lower than that absorption of ArF photoresist. Use of high EUV dose is not high-volume manufacturing friendly, due to a relatively low throughput. Therefore, methods of reducing EUV dose during lithography, without sacrificing lithography performance (e.g., forming stochastic defects), is desirable.

Secondary electrons generated from an underlayer can enhance the PAG (photo acid generator) reactions in CAR (chemically-amplified resist), which is desirable to reduce the EUV dose. Various techniques to increase the secondary electron emission of an underlayer include (1) use of doping metals with higher secondary electron emission to increase electron emission—however, this method suffers from potential metal contamination—e.g., in an EUV scanner—and variations in surface energy, which can affect adhesion of the photoresist; and (2) use of dry resists and dry development, but such methods may result in undesirably high feature or line width roughness, and metal(s) in such dry resists may cause contamination in the EUV scanners. Accordingly, improved EUV methods and structures are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to photoresist underlayer structures, including bulk layers and adhesion layers, and to methods of forming the layers and structures. While the ways in which various embodiments of the present disclosure address drawbacks of prior methods and structures are discussed in more detail below, in general, various embodiments of the disclosure provide structures that can include a relatively thin, uniform bulk layer with desired properties, such as desired etch selectivity, pattern quality, pattern stability, and that allow for reduced EUV dose during an exposure step of a lithography process. Exemplary bulk layers can be formed using a cyclical process, such as a plasma-enhanced cyclical deposition process, which allows for precise control of a thickness of the bulk layer—both on a surface of a substrate and from substrate to substrate. In addition, as set forth in more detail below, an additional adhesion layer can be formed to provide desired surface energy to promote desired adhesion between the bulk layers and overlying photoresist.

In accordance with exemplary embodiments of the disclosure, a method of forming a photoresist underlayers structure comprising a bulk layer includes providing a substrate within a reaction chamber, forming a porous bulk layer (sometimes referred to herein simply as bulk layer) using a first plasma process overlying a surface of the substrate, and forming an adhesion layer overlying the bulk layer. The adhesion layer can be interposed between and in contact with both the bulk layer and a photoresist layer. Examples of the disclosure can further include forming the (e.g., EUV) photoresist layer overlying the adhesion layer. The adhesion layer can be formed using a second cyclic deposition process that includes providing a silicon precursor to the reaction chamber, providing an inert gas into the reaction chamber, and forming a plasma using the inert gas to form activated species that react with the silicon precursor or a derivative thereof to form the adhesion layer. The bulk layer can include one or more of silicon and a metal. For example, the bulk layer can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. When the bulk layer comprises silicon, the same or a different silicon precursor can be used to form the bulk layer and the adhesion layer. As set forth in more detail below, a relatively low plasma density can be used during the step of forming the porous bulk layer using the first plasma process to obtain desired properties, which allows for lower EUV doses during lithography exposure steps.

In accordance with additional exemplary embodiments of the disclosure, a structure that includes a bulk layer and an adhesion layer is provided. The bulk layer and/or adhesion layer can be formed using a method as described herein. The bulk layer can include, for example, a layer comprising a metal and/or silicon. The adhesion layer can include silicon. The adhesion layer can have surface energy properties as described herein. Exemplary structures can also include a layer of photoresist, such as negative tone or positive tone EUV photoresist.

In accordance with further examples of the disclosure, a system for performing a method as described herein is provided. Exemplary systems include a reaction chamber, a silicon precursor source fluidly coupled to the reaction chamber, an inert gas source fluidly coupled to the reaction chamber, and a controller configured to perform a method as described herein or a portion thereof.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a method in accordance with exemplary embodiments of the disclosure.

FIG. 3 illustrates a timing sequence in accordance with examples of the disclosure.

FIG. 4 illustrates critical dimension and EUV dose in accordance with examples of the disclosure.

FIG. 5 illustrates structures formed using various conditions accordance with examples of the disclosure.

FIG. 6 illustrates a structure in accordance with exemplary embodiments of the disclosure.

FIG. 7 illustrates a system configured for executing a method as described herein.

FIG. 8 illustrates a system in accordance with yet additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming structures that include a photoresist underlayer that includes a bulk layer and an adhesion layer and to structures including a photoresist underlayer. As described in more detail below, exemplary methods can be used to form photoresist underlay structures with bulk layers and adhesion layers that provide desired properties, such as desired bulk layer thickness (e.g., less than 10 or less than 5 nm), relatively low surface roughness, good adhesion to the photoresist, desired etch selectivity, desired thickness uniformity—both within a substrate (e.g., a wafer) and between substrates, high pattern quality (low number of defects and high pattern fidelity), low line width roughness (LWR), photoresist stability during EUV lithography processing—e.g., during any post-exposure bake (PEB), photoresist development, reworking of the substrate, and compatibility with integration (e.g., relatively low deposition temperatures). Further, as set forth in more detail below, structures including a photoresist underlayer formed in accordance with examples of the disclosure can use relatively low EUV dose during an exposure step of a lithography process.

As used herein, the term “substrate” may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor; a reactant may provide an element (such as O, N, C) to a film matrix and become a part of the film matrix. In some cases, the terms precursor and reactant can be used interchangeably. The term “inert gas” refers to a gas that does not take part in a chemical reaction to an appreciable extent and/or a gas that excites a precursor when, for example, RF or microwave power is applied, but unlike a reactant, an inert gas may not become a part of a film matrix to an appreciable extent.

The term “cyclic deposition process” or “cyclical deposition process” may refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” may refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas or an inert gas) may subsequently be introduced into the process chamber for use in converting the chemisorbed precursor to the desired material on the deposition surface. The reactant/inert gas can be capable of further reaction or interaction with the precursor. Purging steps can be utilized during one or more cycles, e.g., during each step of each cycle, to remove any excess precursor from the process chamber and/or remove any excess reactant and/or reaction byproducts from the reaction chamber.

In this disclosure, continuously can refer to one or more of without breaking a vacuum, without interruption as a timeline, without any material intervening step, without changing treatment conditions, immediately thereafter, as a next step, or without an intervening discrete physical or chemical structure or layer between two structures or layers in some embodiments. For example, a reactant and/or an inert or noble gas can be supplied continuously during two or more steps and/or cycles of a method.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

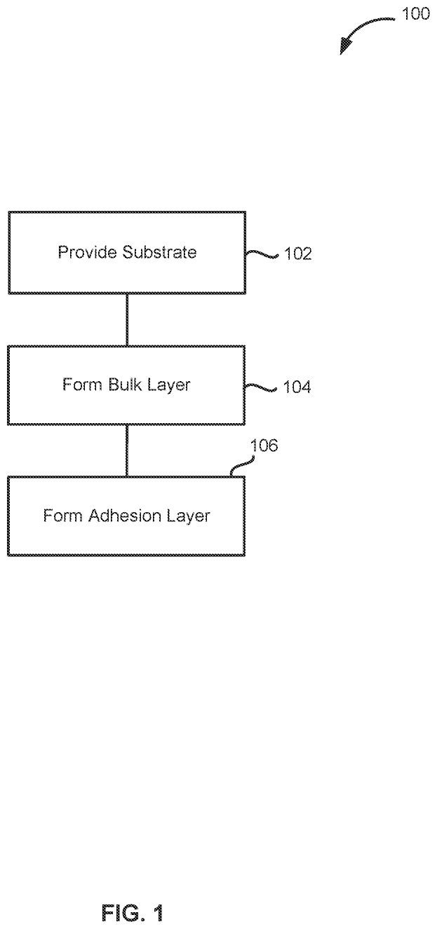

Turning now to the figures, FIG. 1 illustrates a method 100 of forming a structure comprising a photoresist underlayer, including a bulk layer and an adhesion layer, in accordance with exemplary embodiments of the disclosure. Method 100 includes the steps of providing a substrate (step 102), forming a bulk layer (step 104), and forming an adhesion layer (step 106).

Step 102 includes providing a substrate, such as a substrate described herein. The substrate can include one or more layers, including one or more material layers, to be etched. By way of examples, the substrate can include a deposited oxide, a native oxide, and/or an amorphous carbon layer to be etched. The substrate can include several layers underlying the material layer(s) to be etched.

During step 104, a porous bulk layer is formed on a surface of the substrate using a first plasma process. The first plasma process may be a cyclical deposition process. Use of a cyclical deposition process may be desirable, because such a process allows for the formation of a bulk layer with desired thickness—e.g., less than 10 nm or less than or about equal to 5 nm, with improved thickness uniformity—both within a substrate and from substrate-to-substrate. Using a plasma-enhanced process may be desirable, because plasma-enhanced processes allow for deposition of the bulk layer material at relatively low temperatures and/or relatively high rates—compared to thermal processes.

In accordance with examples of the disclosure, a temperature within a reaction chamber during step 104 can be less than 500° C., less than 300° C., less than 100° C. or between about 50° C. and about 500° C., or about 50° C. and about 300° C. or about 50° C. to about 100° C. A pressure within the reaction chamber during step 104 can be between about 200 Pa and about 800 Pa or between about 100 Pa and about 2000 Pa.

In accordance with exemplary embodiments of the disclosure, step 104 includes forming or depositing one or more of a silicon or metal oxide, a silicon or metal nitride, and a silicon or metal oxynitride. Such oxides, nitrides, and/or oxynitrides can also include carbon.

The bulk layer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. The metal can include, for example, one or more metals selected from the group consisting of titanium, tantalum, tungsten, tin, and hafnium. In some cases, the bulk layer includes carbon. The carbon can be incorporated into the bulk layer as the bulk layer is deposited and/or a carbon treatment can be applied to a surface of the bulk layer. Additionally or alternatively, a carbon-containing layer or other layer can be deposited onto a surface of the bulk layer. A thickness of the bulk layer can be less than 10 nm, less than 5 nm, or greater than 2 and less than 10 nm.

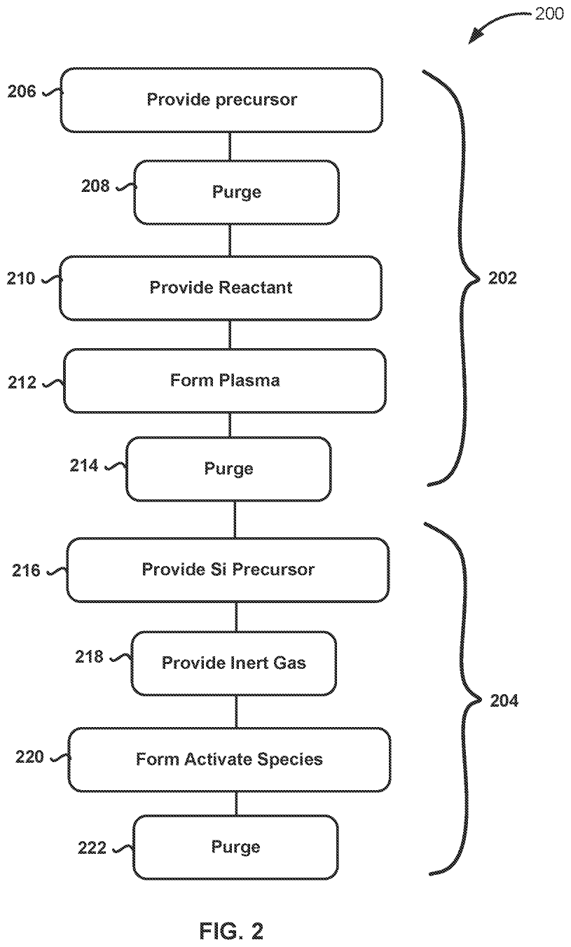

A cyclical process 202 suitable for forming the bulk layer in accordance with step 104 is illustrated in FIG. 2. Cyclical process 202 can include pulsing a (e.g., first) precursor comprising a metal or silicon into a reaction chamber (step 206), pulsing a reactant comprising an oxidant and/or nitriding agent into the reaction chamber (step 210), and forming a plasma (step 212). Cyclical process 202 can be repeated—e.g., between about 10 and about 50 or between about 100 and about 200 times before method 100 proceeds to step 106.

In some cases, the cyclical process for forming the bulk layer can include (A) pulsing a first precursor comprising a metal into a reaction chamber, (B) pulsing a second precursor or reactant comprising an oxidant and/or nitriding agent into the reaction chamber, and (C) pulsing a carbon precursor into the reaction chamber. Each of the pulses can be separated by a purge step. Further, each pulsing step or a combination of pulsing steps (e.g., pulsing steps (A) and (B)) can be repeated a number of times prior to proceeding to the next step to tune a composition of the bulk layer. For example, a range of ratios of (AB):C can be about 1:1 to about 1:10. Unless otherwise noted, steps (A) and (B) or steps (A), (B), and (C) can be performed in any order and various combinations of the steps can be repeated. In these cases, a plasma can be formed during one or more of steps (A), (B), and (C), such as (B) and/or (C).

In accordance with exemplary aspects of the disclosure, a precursor comprising silicon is provided during step 206. In some cases, the silicon precursor can also include carbon. Exemplary silicon precursors suitable for use in forming a bulk layer include silicon precursors noted below in connection with process 204.

In accordance with other exemplary aspects of the disclosure, a precursor provided during step 206 comprises a metal. In these cases, the precursor can include a transition metal, such as one or more metals selected from the group consisting of titanium, tantalum, tungsten, tin, and hafnium. The precursor comprising a metal can also include carbon—e.g., one or more organic groups bonded directly or indirectly to a metal atom. By way of particular examples, the precursor comprising a metal can include a metal halide or a metal organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halide, or other metal-containing compounds.

When used, the carbon precursor can include any suitable organic compound, such as compounds comprising carbon and oxygen. In some cases, the carbon precursor can also include nitrogen. The carbon precursor can be selected to react with, for example, an —OH terminated surface of metal oxides and/or a —NH₂ terminated surface of a metal nitride. Examples of suitable carbon precursors include one or more of organic compounds, such as acid anhydrate (e.g., an acetic anhydrate), toluene, diethylene glycol, triethylene glycol, acetaldehyde, and organosilicon compounds, such as silanes, and siloxanes. Exemplary organosilicon compounds include (n,n-dimethylamino)trimethylsilane, trimethoxy(octadecyl)silane, hexamethyldisilazane, trimethoxy(3,3,3-trifluoropropyl)silane, trimethoxyphenylsilane, trichloro(3,3,3-trifluoropropyl)silane and hexamethyldisilazane.

The precursor flowrate including carrier gas can be between about 10 and about 6000 sccm. A precursor feed or pulse time during step 206 can be greater than 0.01 seconds or greater than 0.15 seconds or between about 0.1 and about 2 seconds or between about 0.01 and about 4 seconds.

The reactant provided during step 210 can include an oxidizing reactant, a nitriding reactant, or a reducing agent, such as a hydrogen-containing reactant. The oxidizing and/or nitriding reactant include reactants that include one or more of oxygen and nitrogen. In some cases, the reactant can include both nitrogen and oxygen. And, in some cases, the two or more oxidizing and/or nitriding reactant can be included in a single pulse. Exemplary oxidizing and nitriding agents include oxygen (O₂), water (H₂O), ozone (O₃), hydrogen peroxide (H₂O₂), ammonia (NH₃), diazene (N₂H₂), CO₂, nitrous oxide (N₂O); exemplary hydrogen-containing reactants include hydrogen (H₂) and the like.

In some cases, the reactant can be continuously flowed to the reaction chamber during one or more deposition cycles of process 202. A reactant flowrate during step 210 can be between about 5 and about 100 sccm or between about 0.1 and about 6 slm.

During step 212, the (e.g., oxidizing, nitriding, or reducing) reactant can be exposed to a (e.g., direct) plasma to form excited species for use in a PEALD process using the first plasma process. In accordance with examples of the disclosure, the first plasma process is configured to provide a relatively low plasma density. As set forth in more detail below, use of the low plasma density is thought to result in an underlayer and/or a bilayer of the bulk layer and adhesion layer with desired properties.

In accordance with examples of the disclosure, a plasma power is relatively low. For example, the first plasma process can be less than 150 W or between about 10 and about 150 W or between about 10 and about 400 W or between about 10 and 1000 W.

Additionally or alternatively, the plasma on time can be relatively short. For example, the plasma on time during the step of forming a porous bulk layer can be less than 4 seconds or less than 2 seconds or between about 0.1 and about 4 seconds.

Additionally or alternatively, a gap between a plasma electrode and a substrate can be set to obtain desired plasma conditions. For example, the gap can be between about 7 mm and about 15 mm or between about 6 mm and about 18 mm.

During steps 208 and 214, any excess precursor and/or any reaction byproducts can be purged from the reaction chamber. The purge can be performed by, for example, supplying an inert gas and/or reactant to the reaction chamber and/or using a vacuum source. For example, a precursor purge time during step 208 can be between about 0.2 and about 0.6 seconds or between about 0.15 and about 1 second or between about 0.1 and about 4 seconds.

Once the bulk layer is formed, an adhesion layer is formed during step 106 using a second plasma process. Step 106 can be performed in situ—within the same reaction chamber and without an air and/or a vacuum break.

Step 106 can be performed using process 204, illustrated in FIG. 2. Step 106/process 204 can be or include a cyclical deposition process, such as a PEALD process. For example, process 204 can include pulsing a silicon precursor to a reaction chamber (step 216), allowing the silicon precursor to react with a surface of a substrate, optionally purging any unreacted precursor and/or byproducts, providing an inert gas to the reaction chamber (step 218), and forming activated species (step 220)—e.g., by forming a plasma using the inert gas to form activated species that react with the silicon precursor or a derivative thereof to form the adhesion layer, and purging any excess reactive species and/or byproducts from the reaction chamber (step 222). Process 204 (i.e., steps 216-222) can be repeated a number of times—e.g., about 10 to about 50 or about 150 to about 200 or about 300 to about 400 times, such that a thickness of the bilayer comprising the bulk layer and the adhesion layer increases by less than 10 nm, less than 5 nm, or less than 0.5 nm during process 204. A thickness of the adhesion layer can be greater than 0 nm and less than 2 nm.

The temperature and pressure during step 106/process 204 can be the same or similar or different for step 102 and/or 104.

During step 216, a silicon precursor is provided to the reaction chamber. In accordance with examples of the disclosure, the silicon precursor does not comprise nitrogen. N-free precursors can be beneficial for use in forming an adhesion layer, because nitrogen is thought to exhibit a poisoning effect due to the presence of N atoms. In accordance with further examples, the silicon precursor consists of or consists essentially of Si, C, H, and O, which may be provided to the reaction chamber with the aid of a carrier gas. By way of examples, the silicon precursor can be selected from one or more of the group consisting of:

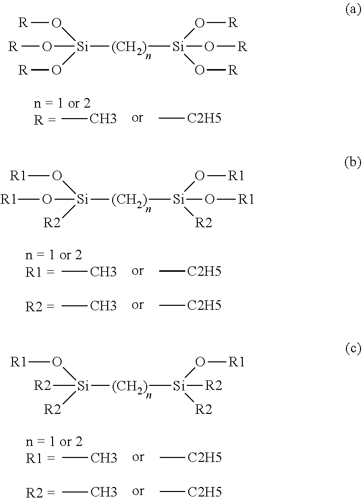

In accordance with further examples, the silicon precursor comprises a carbon-carbon double bond. By way of examples, the silicon precursor can be selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetra methoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane, and dimethoxymethylvinylsilane. By way of particular example, the silicon precursor can be or include 3-methoxypropyltrimethoxysilane or dimethoxymethylvinylsilane.

A flowrate of the silicon precursor and any carrier gas during step 216 can be between about 10 sccm and about 6000 sccm. A duration of step 216 can be between about 0.1 s and about 4 s. Any excess silicon precursor and/or any reaction byproducts can be purged from the reaction chamber after step 216. The purge can be performed by supplying an inert gas to the reaction chamber and/or using a vacuum source.

During step 218, an inert gas is provided into the reaction chamber. The inert gas can be or include one or more of Ar, He, Ne, Kr, H₂ and Xe. A flowrate of the inert gas can be between about 6 slm and about 10 slm. In some cases, the inert gas can be continuously provided during one or more of steps 216-222.

During steps 220, a plasma is formed using the inert gas. A power to form the plasma can be about 30 W to about 400 W or between about 10 W and about 1000 W. A frequency of the power to form the plasma can be between about 200 kHz and about 2.45 GHz. A duration of step 220 can be between about 0.1 s and about 4 s.

During step 222, the plasma power is switched off and any excess reactive species and/or byproducts are purged. Process 204 can be repeated a number of times to form a silicon-based adhesion layer of a desired thickness—e.g., greater than 0 and less than about 6 nm—and the resulting photoresist underlayer.

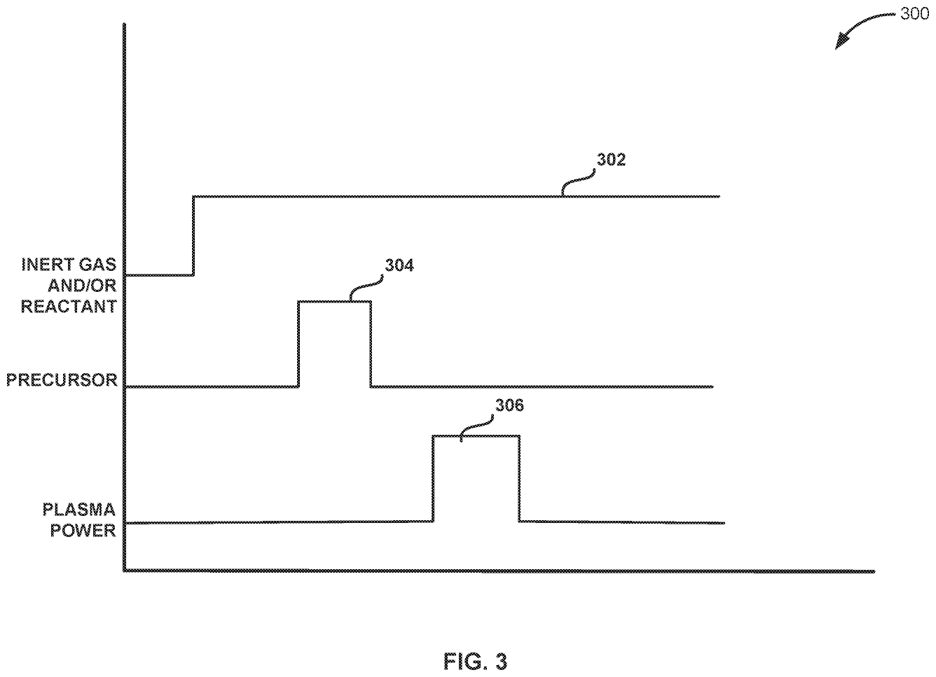

FIG. 3 illustrates a timing sequence suitable for use with process 202 and/or 204. As illustrated, a reactant and/or inert gas can be provided to the reaction chamber continuously (line 302) through one or more precursor pulses 304 and/or plasma power pulses 306. Exemplary precursor and power pulses are described above in connection with steps 206, 212, 216, and 220.

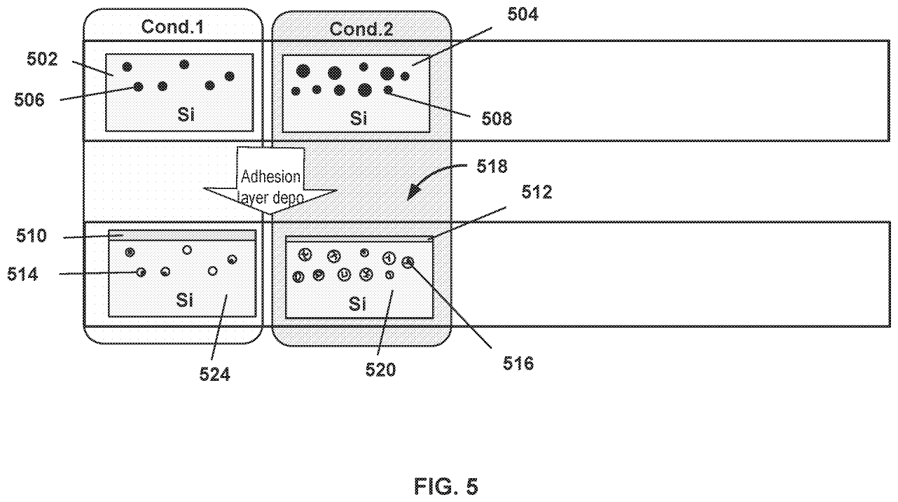

During process 204, a density of silicon in the porous bulk layer formed during process 202 can increase as a result of the step of forming the adhesion layer. FIG. 5 illustrates a proposed mechanism for the increase in density of the porous bulk layer during the step of forming the adhesion layer 106. Condition 1 includes a relatively high plasma density during step 212 and condition 2 includes a relatively low plasma density during step 212. As illustrated, porous bulk layer 504 formed using condition 2 includes more and larger micropores 508, compared to micropores 506 in porous bulk layer 502 formed using condition 1. In the illustrated examples, the process conditions for condition 1 and condition 2 were the same, except the plasma power for condition 1 during step 212 was 150 W and for condition 2, the plasma power during step 212 was 100 W.

During or after formation of an adhesion/glue layer 510 using condition 1, various elements 514, such as H, O, and C, can be incorporated into porous bulk layer 502. A greater amount or higher density of elements 516, such as H, 0, and C, can be incorporated into porous bulk layer 520, compared inclusion of such elements 514 in porous bulk layer 524, as a result of the step of forming the adhesion layer 510, 512, resulting in higher density of bulk layer 520, compared to bulk layer 524 after process 204. Further, an overall thickness of a bilayer 518, including a bulk layer 520 and an adhesion layer 512, can be thinner for the same process 204, compared to a bilayer 522, including a bulk layer 524 and an adhesion layer 510.

Table 1 illustrates exemplary densities and compositions of porous bulk layer (bulk) and bilayers including the porous bulk layer and an adhesion layer (glue layer), illustrating the initial lower densities of porous bulk layers formed using condition 2, relative to the porous bulk layers formed using condition 1, and the higher densities of the bilayers formed using condition 2, relative to the bilayers formed using condition 1 after formation of the adhesion/glue layer.

| HRF of Bulk | | RBS-HFS | | | | |
|---|---|---|---|---|---|---|
| layer (W) | Film | Density(at/cm [symbol] ) | Si (at/cm²) | H(at/cm³) | O(at/cm [symbol] ) | Thickness(nm) |
| 1 [symbol] 0 | Bulk cond. 1 layer | 7.03E22 | 1.95E+22 | 5.98E+21 | 4.48E+22 | 114 |
| | (1100 cyc) | | | | | |
| 100 | Bulk cond. 2 layer only | [symbol] .86E22 | 2.07E+22 | 7.63E+21 | 4. [symbol] 0E+22 | 81.5 |
| | (1100 cyc) | | | | | |
| 1 [symbol] 0 | Bulk cond. 1 layer (1100 | 7.13E22 | 2.09E+22 | 4.53E+21 | 4.32E+22 | 118 |
| | cyc) + Glue layer (1000 | | | | | |
| | cyc) | | | | | |
| 100 | Bulk cond. 2 layer (1100 | 7.24E22 | 2.01E+22 | 8. [symbol] 9E+21 | 4.3 [symbol] E+22 | 82 |
| | cyc) + Glue layer (1000 | | | | | |
| | cyc) | | | | | |

[symbol]

indicates data missing or illegible when filed

The lower film density of porous bulk layer formed using condition 2, relative to condition 1, may include a higher porosity. As a result, more H, O and C atoms originating from the adhesion layer may be incorporated into the micropores 508, suggesting a further decrease of the condition 2 bilayer volume, and thereby increasing the condition 2 bilayer (photoresist underlayer) density more than that of the condition 1 bilayer. Here, a higher bilayer density will emit more secondary electrons after absorbing EUV photons, which will enhance the PAG reactions during EUV lithography and reduce the required EUV photons in the end.

Further, the condition 2 bilayer contains relatively less Si and more O atoms, which can lead to a higher secondary electron emission, resulting in a reduction of EUV dose. The adhesion layer may be carbon-rich and, like O, when incorporated into micropores 508, the C can facilitate emission of more secondary electrons than silicon.

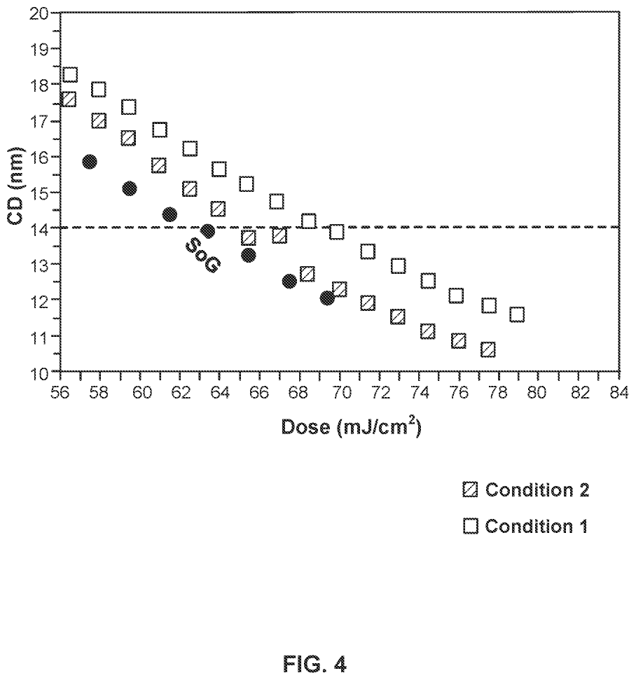

FIG. 4 illustrates a reduction in EUV dose for critical dimensions (CD) that results from the bilayer (photoresist underlayer) formed using condition 2, relative to condition 1. In this example, the bilayer (photoresist underlayer) formed according to condition 2 exhibits about a 7% EUV (˜5 mJ/cm²) dose reduction compared to the bilayer (photoresist underlayer) formed according to condition 1, and it is very close to the dose of spin-on-glass (SoG).

Methods in accordance with the disclosure can also include a step of forming a photoresist layer overlying and in contact with the adhesion layer. The photoresist can be deposited using, for example, spin-on techniques. The photoresist layer can be or include positive or negative tone extreme ultraviolet (EUV) lithography photoresist.

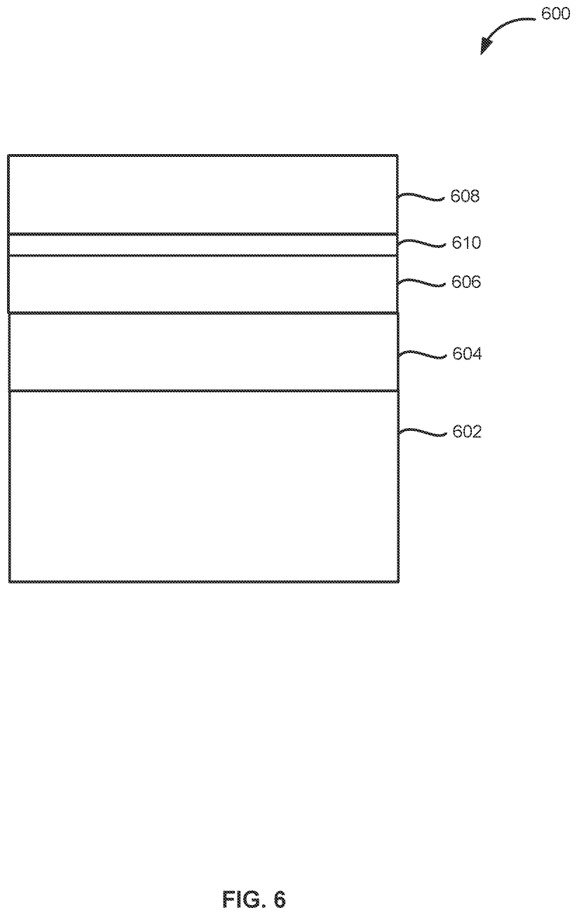

FIG. 6 illustrates a structure 600 in accordance with exemplary embodiments of the disclosure. Structure 600 can be formed using, for example, method 100 and/or 200 and/or timing sequence 300.

As illustrated, structure 600 includes a substrate 602, a material layer 604, a photoresist underlayer including a bulk layer 606 and an adhesion layer 610, and a photoresist layer 608. Adhesion layer 610 forms part of the photoresist underlayer and is between and in contact with bulk layer 606 and photoresist layer 608.

Substrate 602 can include a substrate as described above. By way of examples, substrate 602 can include a semiconductor substrate, such as a bulk material, such as silicon (e.g., single-crystal silicon), other Group IV semiconductor material, Group III-V semiconductor material, and/or Group II-VI semiconductor material and can include one or more layers (e.g., a patterning stack) overlying the bulk material. Further, as noted above, substrate 602 can include various topologies, such as recesses, lines, and the like formed within or on at least a portion of a layer of the substrate.

Material layer 604 can be patterned and etched using a photoresist underlayer and a layer of photoresist as described herein. Exemplary materials suitable for material layer 304 include, for example, oxides, such as native oxides or field oxides. Other exemplary material layer 604 materials include amorphous carbon, nitrides, other oxides, silicon, and add-on films (e.g., a self-assembled monolayer (e.g., hexamethyldisilazane (HMDS)).

Bulk layer 606 can include a bulk layer formed in accordance with a method described herein (e.g., method 100) and/or have properties and/or material as described herein. Exemplary bulk layers include one or more of a silicon or metal oxide, a silicon or metal nitride, and a silicon or metal oxynitride—any of which can include or not include carbon. For example, bulk layer 606 can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

A thickness of bulk layer 606 can depend on a composition of material layer 604, a thickness of material layer 604, a type of photoresist, and the like. In accordance with examples of the disclosure, bulk layer 606 has a thickness of less than 10 nm or less than or about 5 nm or between about 3 nm and about 10 nm. If bulk layer 606 is too thick, residual underlayer material may remain after an etch step. If bulk layer 606 is too thin, bulk layer 606 may not provide desired pattern transfer during an etch process.

Adhesion layer 610 desirably exhibits good adhesion and other properties as described herein. In accordance with examples of the disclosure, adhesion layer 610 includes silicon and can optionally include one or more of carbon, hydrogen, and oxygen. As noted above, adhesion layer 610 may desirably not include nitrogen.

To provide desired adhesion between photoresist layer 608 and bulk layer 606, adhesion layer 610 may have or be tuned to have desired surface chemistry properties, e.g., quantified as surface energy, which is further categorized into a polar part of surface energy and a disperse part of surface energy. The polar part of surface energy and the disperse part of surface energy of bulk layer 606 can be calculated by measuring a contact angle of a liquid, such as water or CH₂I₂, and using the Owens, Wendt, Rabel and Kaelble (OWRK) method to determine the polar part and the disperse part of the surface energy. The same properties can be measured and calculated for photoresist layer 608. A thickness of adhesion layer 610 can be greater than 0 nm and less than 6 nm.

In accordance with various examples of the disclosure, a value of a polar part of surface energy of adhesion layer 610 is between about 5 mN/m to about 25 mN/m or between about 20 mN/m to about 40 mN/m. In accordance with further examples, a value of a dispersive part of surface energy of adhesion layer 610 is between about 20 mN/m to about 40 mN/m, or between about 10 mN/m to about 40 mN/m, or between about 5 mN/m to about 50 mN/m. For example, when photoresist layer 608 comprises negative tone photoresist, a value of the polar part of surface energy of the adhesion layer can be between about 20 mN/m and about 40 mN/m and/or a dispersive part of surface energy of the adhesion layer can be between about 10 mN/m and about 30 mN/m or between about 20 mN/m and about 40 mN/m. When photoresist layer 608 includes positive tone photoresist, a value of the polar part of surface energy of the adhesion layer can be between about 5 mN/m and about 25 mN/m and/or a value of the dispersive part of surface energy of the adhesion layer can be between about 10 mN/m and about 30 mN/m.

By way of examples, with the utilization of an inert gas plasma to form adhesion layer 610, dangling bonds potentially behave as the surface reactive sites and lead to the chemisorption when the silicon precursor is introduced onto the film. Hence, ligands (e.g., CHx ligands) in the silicon precursor structure can eventually remain on the surface, which results in a desired surface free energy. Adhesive layer 610 can be intrinsically SiOC, ending up with surface hydrocarbons.

Photoresist layer 608 can be or include positive or negative tone (e.g., EUV) photoresist.

As noted above, a density of a bilayer comprising or consisting of bulk layer 606 and adhesion layer 610 may desirably be high, even though an initial density of a deposited bulk may be relatively low. In accordance with examples of the disclosure, a density of a bilayer comprising the bulk layer and the adhesion layer is greater than 6.86E22 or greater than 7.24E22 at/cm³.

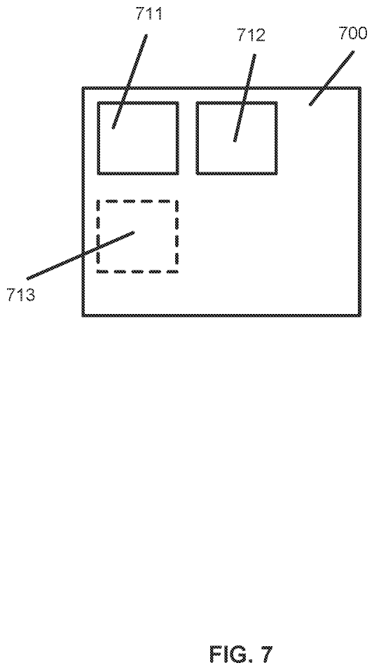

FIG. 7 illustrates a system 700 configured for executing a method as described herein. System 700 comprises at least one reaction chamber which is configured for depositing an underlayer, including a bulk layer and an adhesion layer as described herein. System 700 may comprise a first reaction chamber 711 and a second reaction chamber 712 that may both be configured for depositing a bulk layer and forming an adhesion layer as described herein, or a part thereof. If desired, system 700 can include a third reaction chamber 713 in which another process, such as a thermal or plasma-enhanced post treatment, may be carried out.

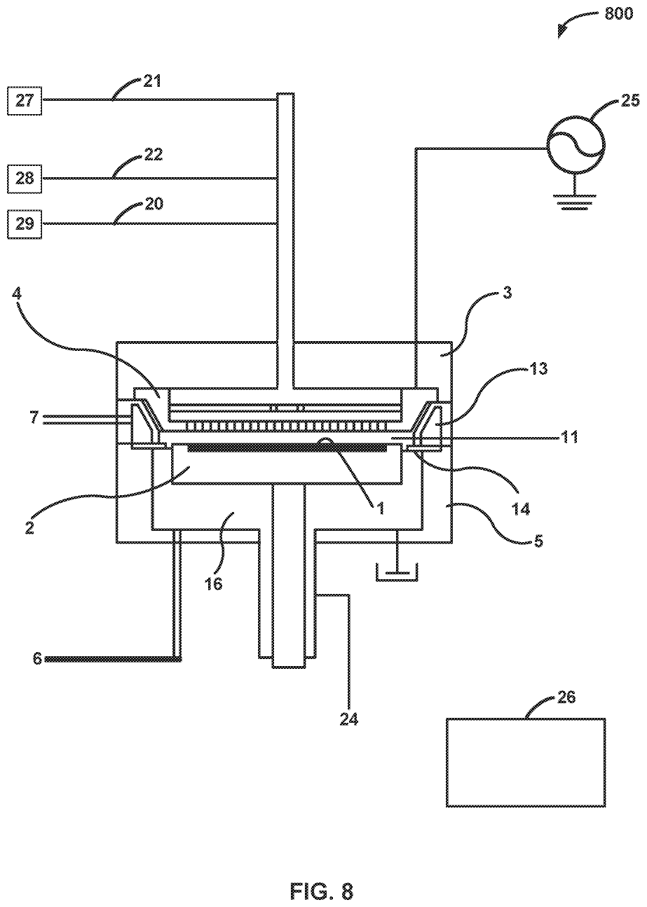

FIG. 8 illustrates an exemplary reactor system 800 in greater detail. Reactor system 800 can be used to perform one or more steps or sub steps as described herein and/or to form one or more structures or portions thereof as described herein.

Reactor system 800 includes a pair of electrically conductive flat-plate electrodes 4, 2 in parallel and facing each other in the interior 11 (reaction zone) of a reaction chamber 3. Reaction chamber 3 can be suitable for use as reaction chamber 711-713. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 800 can include any suitable number of gas lines. Gas line 20 can be coupled to a silicon precursor source 29, gas line 21 can be coupled to an inert gas source 27, and gas line 22 can be coupled to another (e.g., reactant) gas source 28.

In reaction chamber 3, a circular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition steps and treatment steps are performed in the same reaction space, so that two or more (e.g., all) of the (e.g., deposition and adhesion layer) steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 800 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a silicon precursor and an inert gas to form an adhesion layer on a bulk layer. Additionally or alternatively, the controller can be configured to perform steps to form a porous bulk layer as described herein.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising a photoresist underlayer layer that comprises a bulk layer and an adhesion layer, the method comprising the steps of:
providing a substrate within a reaction chamber;
forming a porous bulk layer overlying a surface of the substrate using a first plasma process; and
forming an adhesion layer using a second plasma process comprising:
providing a silicon precursor to the reaction chamber;
providing an inert gas into the reaction chamber; and
forming activated species that react with the silicon precursor or a derivative thereof to form the adhesion layer.

2. The method of claim 1, wherein a plasma power during the first plasma process is less than 150 W or between about 10 and about 400 W or between 10 and 1000 W.

3. The method of claim 1, wherein a plasma on time during the step of forming a porous bulk layer is less than 4 seconds or less than 2 seconds or between about 0.1 and about 4 seconds.

4. The method of claim 1, wherein a precursor feed time during the step of forming a porous bulk layer is greater than 0.01 seconds or greater than 0.15 seconds or between about 0.1 and about 2 seconds or between about 0.01 and about 4 seconds.

5. The method of claim 1, wherein a precursor purge time during the step of forming a porous bulk layer is between about 0.2 and about 0.6 seconds or between about 0.15 and about 1 seconds or between about 0.1 and about 4 seconds.

6. The method of claim 1, wherein a pressure during the step of forming a porous bulk layer is between about 200 Pa and about 800 Pa or between about 100 Pa and about 2000 Pa.

7. The method of claim 1, wherein a gap between a plasma electrode and the substrate during the step of forming a porous bulk layer is between about 7 mm and about 15 mm or between about 6 mm and about 18 mm.

8. The method of claim 1, wherein a reactant flowrate during the step of forming a porous bulk layer is between about 5 and about 100 sccm or between about 0.1 and about 6 slm.

9. The method of claim 1, further comprising a step of forming a photoresist layer overlying and in contact with the adhesion layer, wherein the photoresist layer comprises extreme ultraviolet (EUV) lithography photoresist.

10. The method of claim 1, wherein a thickness of the porous bulk layer is greater than 2 and less than 10 nm.

11. The method of claim 1, wherein a density of the porous bulk layer increases during the step of forming the adhesion layer.

12. The method of claim 1, wherein the silicon precursor does not comprise nitrogen.

13. The method of claim 1, wherein the silicon precursor is selected from one or more of the group consisting of:

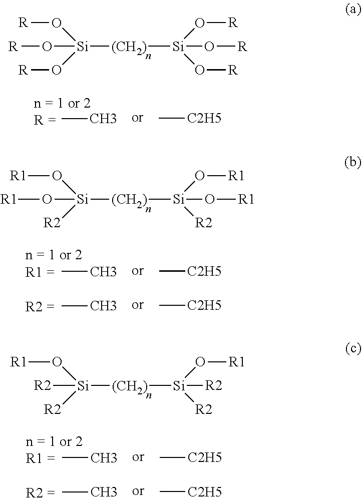

14. The method of claim 1, wherein the silicon precursor comprises a carbon-carbon double bond.

15. The method of claim 1, wherein the silicon precursor is selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetramethoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane, dimethoxymethylvinylsilane.

16. The method of claim 1, wherein the porous bulk layer is formed using a cyclic deposition process.

17. The method of claim 1, wherein the porous bulk layer is formed using the silicon precursor.

18. The method of claim 1, wherein an amount of hydrogen, oxygen, carbon, or any combination thereof in the porous bulk layer increases as a result of the step of forming the adhesion layer.

19. The method of claim 1, wherein the steps of providing a silicon precursor to the reaction chamber, providing an inert gas into the reaction chamber, and forming activated species that react with the silicon precursor or a derivative thereof are repeated between about 10 and about 50 or about 150 or about 200 or about 300 and about 400 times and wherein a thickness of a bilayer comprising the porous bulk layer and the adhesion layer increases by less than 10 nm, less than 5 nm, or less than 0.5 nm.

20. The method of claim 1, wherein a thickness of the adhesion layer is greater than 0 nm and less than 2 nm.

21. The method of claim 16, wherein the cyclic deposition process is repeated between about 10 and about 50 or about 100 and about 200 times.

22. The method of claim 1, wherein a density of silicon in the porous bulk layer decreases as a result of the step of forming the adhesion layer.

23. A structure formed according to the method of claim 1.

24. The structure of claim 23, wherein a density of a bilayer comprising the porous bulk layer and the adhesion layer is greater than 6.86E22 or greater than 7.24E22 at/cm³.

25. The structure of claim 23, wherein the adhesion layer comprises silicon.

26. The structure of claim 23, further comprising EUV photoresist overlying and in contact with the adhesion layer.

27. A reactor system for forming an adhesion layer, the system comprising:
a reaction chamber;
a silicon precursor source fluidly coupled to the reaction chamber;
an inert gas source fluidly coupled to the reaction chamber; and
a controller configured to perform the method according to claim 1.
